(19) United States
(12) Patent Application Publication
(10) Pub. No.: US 2025/0241188 A1
(43) Pub. Date: Jul. 24, 2025

(54) DISPLAY DEVICE

(71) Applicant: Japan Display Inc., Tokyo (JP)

(72) Inventor: Yuji MAEDE, Tokyo (JP)

(73) Assignee: Japan Display Inc., Tokyo (JP)

(21) Appl. No.: 19/034,740

(22) Filed: Jan. 23, 2025

(30) Foreign Application Priority Data
Jan. 23, 2024 (JP) 2024-007849

(51) Int. Cl. H10K 59/80; G02F 1/1335; H10K 59/126; H10K 59/38

(52) U.S. Cl. CPC H10K 59/8792; G02F 1/133512; G02F 1/133519; H10K 59/126; H10K 59/38; H10K 59/873

(57) ABSTRACT

According to one embodiment, a display device comprises a substrate, a first display element provided above the substrate, a sealing layer covering the first display element, and an optical control element overlapping the sealing layer. The optical control element comprises a plurality of partitions including a pair of first partitions sandwiching the first display element in plan view, and an optical layer located between the pair of the first partitions, in contact with a side surface of the first partition, and overlapping the first display element. A refractive index of each of the partitions is smaller than a refractive index of the optical layer.

### CROSS-REFERENCE TO RELATED APPLICATIONS

This application is based upon and claims the benefit of priority from Japanese Patent Application No. 2024-007849, filed Jan. 23, 2024, the entire contents of which are incorporated herein by reference.

### FIELD

Embodiments described herein relate generally to a display device.

### BACKGROUND

In recent display devices, it is requested to render a viewing angle at which a certain contrast can be obtained valuable. For example, in display devices mounted on a vehicle such as an automobile, a viewing angle control is requested in which a displayed image is visually recognizable from a side of a passenger seat and, in contrast, a displayed image is visually unrecognizable from a side of a driver seat, for example, at the time of driving.

### BRIEF DESCRIPTION OF THE DRAWINGS

FIG. 1 is a view showing a configuration example of a display device DSP of the first embodiment.

FIG. 2 is a view showing a configuration example of subpixels SP1, SP2, and SP3 of the first embodiment.

FIG. 3 is a view showing a configuration example of surroundings of pixels PX of the first embodiment.

FIG. 4 is a cross-sectional view showing the configuration example of the display device DSP along line A-A′ in FIG. 3.

FIG. 5 is a cross-sectional view showing the configuration example of the display device DSP along line B-B′ in FIG. 3.

FIG. 6 is a view showing another configuration example of the surroundings of the pixels PX of the first embodiment.

FIG. 7 is a cross-sectional view showing the configuration example of the display device DSP along line C-C′ in FIG. 6.

FIG. 8 is a view showing yet another configuration example of the surroundings of the pixels PX of the first embodiment.

FIG. 9 is a view showing yet another configuration example of the surroundings of the pixels PX of the first embodiment.

FIG. 10 is a cross-sectional view showing another configuration example of the display device DSP along line A-A′ in FIG. 3.

FIG. 11 is a cross-sectional view showing yet another configuration example of the display device DSP along line A-A′ in FIG. 3.

FIG. 12 is a view showing yet another configuration example of the surroundings of the pixels PX of the first embodiment.

FIG. 13 is a cross-sectional view showing the configuration example of the display device DSP along line D-D′ in FIG. 12.

FIG. 14 is a view showing yet another configuration example of the surroundings of the pixels PX of the first embodiment.

FIG. 15 is a view showing a configuration example of a display device DSP of the second embodiment.

FIG. 16 is a view showing a configuration example of surroundings of pixels PX of the second embodiment.

FIG. 17 is a cross-sectional view showing the configuration example of the display device DSP along line E-E′ in FIG. 16.

FIG. 18 is a cross-sectional view showing the configuration example of the display device DSP along line F-F′ in FIG. 16.

FIG. 19 is a cross-sectional view showing another configuration example of the display device DSP along line E-E′ in FIG. 16.

FIG. 20 is a cross-sectional view showing yet another configuration example of the display device DSP along line E-E′ in FIG. 16.

### DETAILED DESCRIPTION

In general, according to one embodiment, a display device comprises: a substrate; a first display element provided above the substrate; a sealing layer covering the first display element; and an optical control element overlapping the sealing layer. The optical control element comprises: a plurality of partitions including a pair of first partitions sandwiching the first display element in plan view; and an optical layer located between the pair of the first partitions, in contact with a side surface of the first partition, and overlapping the first display element. A refractive index of each of the partitions is smaller than a refractive index of the optical layer.

According to another embodiment, a display device comprises: a first transparent substrate; a second transparent substrate facing the first transparent substrate; a liquid crystal layer provided between the first transparent substrate and the second transparent substrate; a pixel electrode provided between the first transparent substrate and the second transparent substrate; and an optical control element provided between the second transparent substrate and the liquid crystal layer. The optical control element comprises: a plurality of partitions including a pair of first partitions sandwiching the pixel electrode in plan view; and an optical layer located between the pair of the first partitions, in contact with a side surface of the first partition, and overlapping the pixel electrode. A refractive index of each of the partitions is smaller than a refractive index of the optical layer.

Embodiments described herein can provide a display device capable of limiting viewing angles.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. A plan view is defined as appearance when various types of elements are viewed parallel to the third direction Z.

### First Embodiment

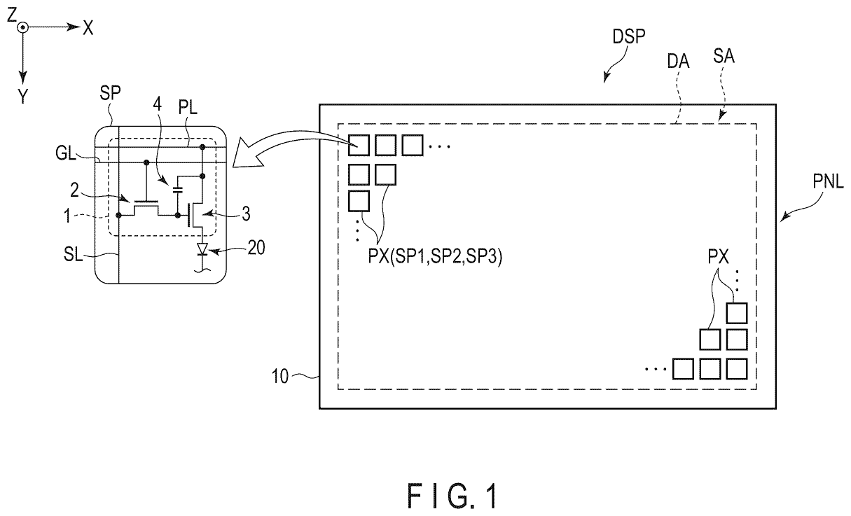

FIG. 1 is a view showing a configuration example of a display device DSP of the first embodiment. The display device DSP of the present embodiment is an organic electroluminescent display device comprising an organic light emitting diode (OLED) as a display element, and can be mounted on televisions, personal computers, vehicle-mounted devices, tablet terminals, smartphones, mobile phones, and the like. The specification describes a display device mounted on a vehicle such as an automobile as an example.

The display device DSP comprises a display panel PNL including a display area DA which displays an image and a surrounding area SA located on an external side relative to the display area DA on an insulating substrate 10. The substrate 10 may be glass or a resinous film having flexibility.

In FIG. 1, the substrate 10 has a rectangular shape having long sides parallel to the first direction X in plan view. The shape of the substrate 10 in a plan view is not limited to this example and may be another shape such as a rectangular shape having long sides parallel to the second direction Y, a square shape, a circular shape, or an elliptic shape.

The display area DA comprises a plurality of pixels PX arranged in a matrix in the first direction X and the second direction Y. Each pixel PX includes a plurality of subpixels SP. As an example, each pixel PX includes a subpixel SP1 which exhibits a first color, a subpixel SP2 which exhibits a second color, and a subpixel SP3 which exhibits a third color. The first, second, and third colors are colors different from each other. Each pixel PX may include a subpixel SP which exhibits another color such as white in addition to the subpixels SP1, SP2, and SP3 or instead of one of the subpixels SP1, SP2, and SP3.

The subpixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. Either a source electrode or a drain electrode of the pixel switch 2 is connected to a signal line SL, and the other is connected to a gate electrode of the drive transistor 3 and the capacitor 4. In the drive transistor 3, one of the source electrode and the drain electrode is connected to a power line PL and the capacitor 4, and the other is connected to the anode of the display element 20.

The configuration of the pixel circuit 1 is not limited to the example shown in the figure. For example, the pixel circuit 1 may comprise more thin-film transistors and capacitors.

The display element 20 is an organic light emitting diode (OLED) as a light emitting element and thus may be called an organic EL element.

Though not described in detail, a terminal for connecting an IC chip and a flexible printed circuit is provided in the surrounding area SA.

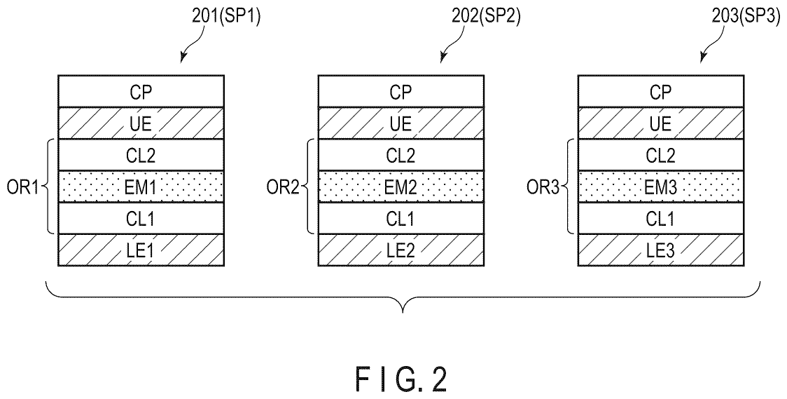

FIG. 2 is a view showing a configuration example of the subpixels SP1, SP2, and SP3 of the first embodiment. The subpixels SP1, SP2, and SP3 comprise display elements 201, 202 and 203, respectively, as the display elements 20.

The display element 201 comprises: a lower electrode LE1; an organic layer OR1 including a light emitting layer EM1; an upper electrode UE; and a cap layer CP. The light emitting layer EM1 overlaps the lower electrode LE1. The upper electrode UE overlaps the lower electrode LE1. The cap layer CP overlaps the upper electrode UE. The organic layer OR1 is provided between the lower electrode LE1 and the upper electrode UE. The light emitting layer EM1 is formed of a material which emits a light beam in a blue wavelength range.

The display element 202 includes: a lower electrode LE2; an organic layer OR2 including a light emitting layer EM2; the upper electrode UE; and the cap layer CP. The light emitting layer EM2 overlaps the lower electrode LE2. The upper electrode UE overlaps the light emitting layer EM2. The cap layer CP overlaps the upper electrode UE. The organic layer OR2 is provided between the lower electrode LE2 and the upper electrode UE. The light emitting layer EM2 is formed of a material which emits a light beam in the green wavelength range, for example.

The display element 203 includes: a lower electrode LE3; an organic layer OR3 including a light emitting layer EM3; the upper electrode UE; and the cap layer CP. The light emitting layer EM3 overlaps the lower electrode LE3. The upper electrode UE overlaps the light emitting layer EM3. The cap layer CP overlaps the upper electrode UE. The organic layer OR3 is provided between the lower electrode LE3 and the upper electrode UE. The light emitting layer EM3 is formed of a material which emits a light beam in the red wavelength range.

For example, the lower electrodes LE1, LE2, and LE3 correspond to the anodes of the display elements, and the upper electrode UE corresponds to the cathodes of the display elements or a common electrode.

In the example shown in the figure, each of the organic layers OR1, OR2, and OR3 includes a common layer CL1 and a common layer CL2.

The common layer CL1 has, for example, a hole injection layer, a hole transport layer, and an electron blocking layer. The common layer CL1 is provided between the lower electrode LE1 and the light emitting layer EM1, between the lower electrode LE2 and the light emitting layer EM2, and between the lower electrode LE3 and the light emitting layer EM3.

The common layer CL2 has, for example, an electron injection layer, an electron transport layer, and a hole blocking layer. The common layer CL2 is provided between the light emitting layer EM1 and the upper electrode UE, between the light emitting layer EM2 and the upper electrode UE, and between the light emitting layer EM3 and the upper electrode UE.

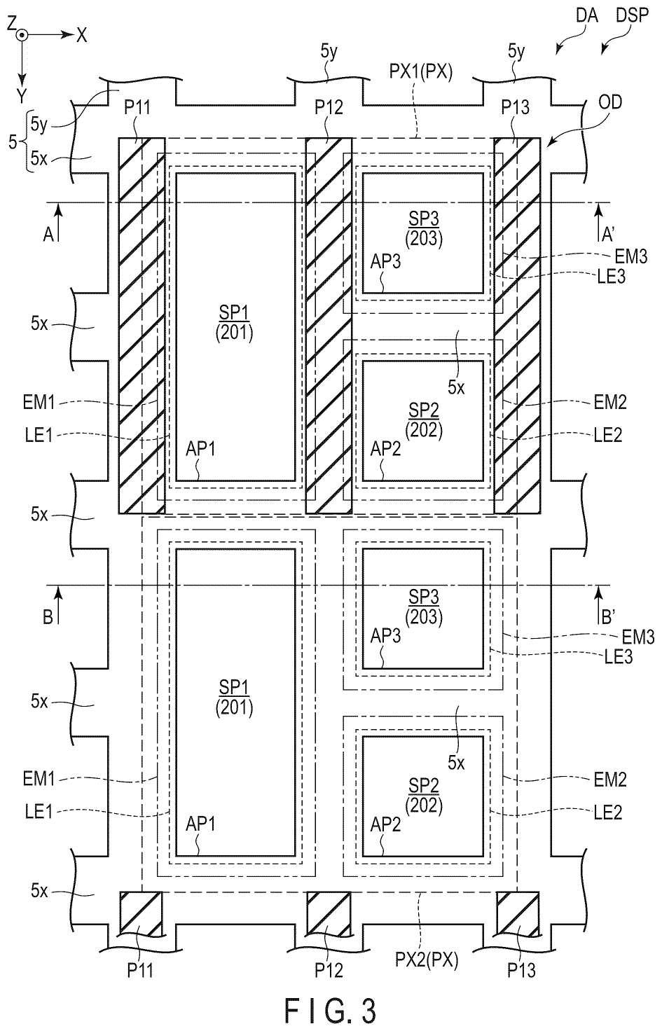

FIG. 3 is a view showing a configuration example of surroundings of pixels PX of the first embodiment.

The pixel PX includes a pixel PX1 and a pixel PX2 adjacent to each other along the second direction Y. In the illustrated example, the display area DA has rows in each of which the pixel PX1 and the pixel PX2 are alternately formed in the second direction Y. These rows are arranged in the first direction X. Each of the pixels PX1 and PX2 includes the subpixels SP1, SP2, and SP3.

In the example of FIG. 3, the subpixels SP2 and SP3 are arranged in the second direction Y. The subpixels SP1 and SP2 are arranged in the first direction X. The subpixels SP1 and SP3 are arranged in the first direction X.

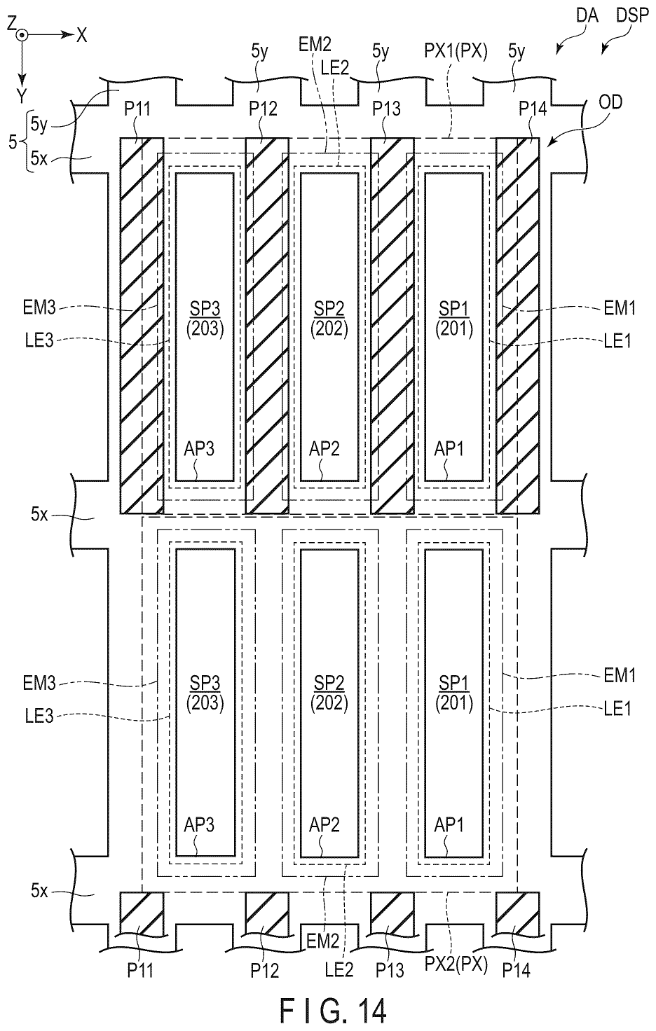

When the subpixels SP1, SP2, and SP3 are arranged in the layout shown in this layout, a row in which the plurality of subpixels SP1 are arranged in the second direction Y and a row in which the plurality of subpixels SP2 and SP3 are alternately arranged in the second direction Y are formed in the display area DA. These rows are alternately arranged in the first direction X. The layout of the subpixels SP1, SP2, and SP3 is not limited to the example of FIG. 3. As another example, as shown in FIG. 14, the subpixels SP1, SP2, and SP3 of each pixel PX may be arranged in an order in the first direction X. This layout is described later in detail.

The display device DSP further comprises a rib 5. The rib 5 includes apertures AP1, AP2, and AP3 in the subpixels SP1, SP2, and SP3, respectively. In the shown example, the area of the aperture AP1 is greater than each of the area of the aperture AP2 and the area of the AP3. The area of the aperture AP2 is greater than the area of the aperture AP3. The areas of the apertures AP1, AP2, and AP3 may be different from or equivalent to one another.

The rib 5 includes a plurality of ribs 5x extending along the first direction X and a plurality of ribs 5y extending along the second direction Y. The plurality of ribs 5x are provided between two apertures AP1 adjacent to each other in the second direction Y and between the aperture AP2 and the aperture AP3 adjacent to each other in the second direction Y. The plurality of ribs 5y are provided between the apertures AP1 and AP2 adjacent to each other in the first direction X and between the apertures AP1 and AP3 adjacent to each other in the first direction X.

In the example of FIG. 3, the rib 5x and the rib 5y are connected to each other. The rib 5 is formed into a grating shape surrounding the apertures AP1, AP2, and AP3.

In the display element 201 of the subpixel SP1, the aperture AP1 overlaps the lower electrode LE1 and the light emitting layer EM1. The lower electrode LE1 is electrically connected to the pixel circuit 1 (refer to FIG. 1) of the subpixel SP1. The periphery of each of the lower electrode LE1 and the light emitting layer EM1 overlaps the rib 5. The lower electrode LE1 and the light emitting layer EM1 are surrounded by the rib 5.

In the display element 202 of the subpixel SP2, the aperture AP2 overlaps the lower electrode LE2 and the light emitting layer EM2. The lower electrode LE2 is electrically connected to the pixel circuit 1 of the subpixel SP2. The periphery of each of the lower electrode LE2 and the light emitting layer EM2 overlaps the rib 5. The lower electrode LE2 and the light emitting layer EM2 are surrounded by the rib 5.

In the display element 203 of the subpixel SP3, the aperture AP3 overlaps the lower electrode LE3 and the light emitting layer EM3. The lower electrode LE3 is electrically connected to the pixel circuit 1 of the subpixel SP3. The periphery of each of the lower electrode LE3 and the light emitting layer EM3 overlaps the rib 5. The lower electrode LE3 and the light emitting layer EM3 are surrounded by the rib 5.

The lower electrodes LE1, LE2, and LE3 are spaced apart from one another. The light emitting layers EM1, EM2, and EM3 are spaced apart from one another.

In the example shown in the figure, the outer shapes of the lower electrodes LE1, LE2, and LE3 are shown by broken lines, and the outer shapes of the light emitting layers EM1, EM2, and EM3 are shown by two-dot chain line. The outer shape of each of the apertures AP1, AP2, and AP3, the lower electrodes LE1, LE2, and LE3 and the light emitting layers EM1, EM2, and EM3 does not necessarily reflect the accurate shape.

The display device DSP further comprises partitions P11, P12, and P13 included in an optical control element OD. The partitions P11, P12, and P13 extend in the second direction Y in which the pixels PX1 and PX2 are arranged. The partitions P11 and P13 are arranged between two pixels PX1 adjacent to each other in the first direction X. The partitions P11 and P13 sandwich the pixel PX1 along the first direction X in plan view. The partition P12 is provided between the display element 201 and the display element 202 adjacent to each other in the first direction X in the pixel PX1 and between the display element 201 and the display element 203 adjacent to each other in the first direction X in the pixel PX1. The partitions P11 and P12 sandwich the display element 201 along the first direction X in plan view. The partitions P12 and P13 sandwich each of the display elements 202 and 203 along the first direction X in plan view.

The partitions P11, P12, and P13 overlap the rib 5 in the third direction Z. The partitions P11, P12, and P13 overlap the pixel PX1 in the third direction Z.

In the illustrated example, the partition P11 overlaps the periphery of light emitting layers EM1 in the third direction Z in the pixel PX1, but does not overlap the lower electrode LE1 and the aperture AP1. The partition P11 may not overlap the light emitting layer EM1 in the third direction Z, and may overlap the lower electrode LE1 and the aperture AP1.

In addition, the partition P12 overlaps the periphery of each of the light emitting layers EM1, EM2, and EM3 in the third direction Z in the pixel PX1, but does not overlap the lower electrodes LE1, LE2, and LE3 and the apertures AP1, AP2, and AP3. In addition, the partition P12 may not overlap the light emitting layers EM1, EM2, and EM3 in the third direction Z, and may overlap the lower electrodes LE1, LE2, and LE3 and the apertures AP1, AP2, and AP3.

In addition, the partition P13 overlaps the periphery of each of the light emitting layers EM2 and EM3 in the third direction Z in the pixel PX1, but does not overlap the lower electrodes LE2 and LE3 and the apertures AP2 and AP3. In addition, the partition P13 may not overlap each of the light emitting layers EM2 and EM3 in the third direction Z, and may overlap the lower electrodes LE2 and LE3 and the apertures AP2 and AP3.

In contrast, the partitions P11, P12, and P13 do not overlap the pixel PX2 in the third direction Z. That is, each of the partitions P11, P12, and P13 extends in the second direction Y but stops before the pixel PX2. The pixel PX2 has no partitions that sandwich each of the subpixels SP1, SP2, and SP3 in plan view. That is, each of the partitions P11, P12, and P13 has a length corresponding to one pixel in the second direction Y. The partitions P11, P12, and P13 are arranged at an interval of one pixel in the second direction Y.

In the example shown in FIG. 3, partitions that overlap pixels are arranged for every other pixels arranged in the extending direction of the partition, but may be arranged for every n-pixels (n is an integer of two or more). That is, each of the partitions has a length of n-pixels in the extending direction of the partition and are arranged at an interval of n-pixels in the extending direction. The length of the partition and the interval between the partitions may be different from each other.

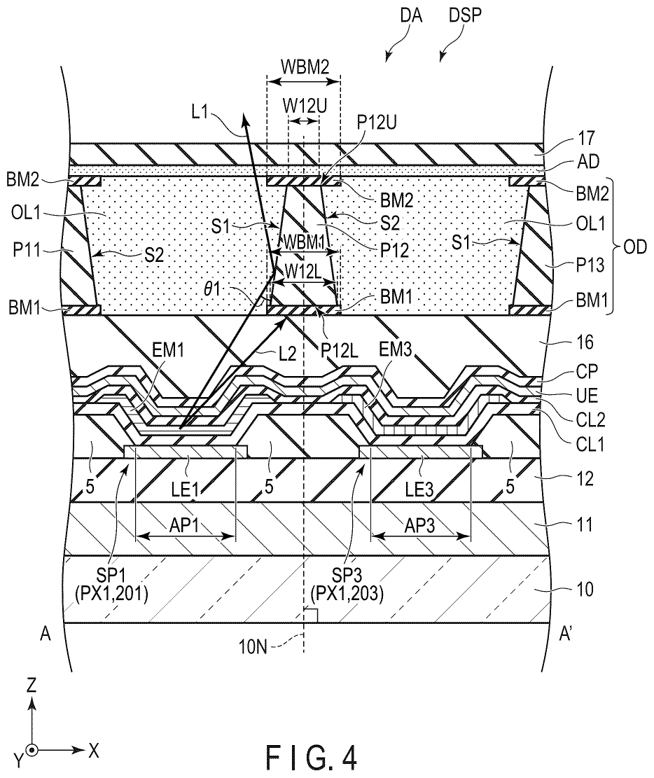

FIG. 4 is a cross-sectional view showing the configuration example of the display device DSP along line A-A′ in FIG. 3. The following describes the display elements 201 and 203 among the display elements 201, 202, and 203 of the pixel PX1. Note that the display element 202 has the same cross section of each of the display elements 201 and 203.

The display device DSP comprises: the substrate 10; the display elements 201 and 203 provided above the substrate 10; a circuit layer 11; an insulating layer 12; a sealing layer 16; the optical control element OD; and a polarizer 17.

The circuit layer 11 is provided on the substrate 10. The circuit layer 11 includes various circuits such as the pixel circuit 1 shown in FIG. 1 and various lines such as the scanning line GL, the signal line SL, and a power line PL. The circuit layer 11 is covered with the insulating layer 12. The insulating layer 12 includes an organic insulating layer which planarizes the irregularities formed by the circuit layer 11.

The lower electrodes LE1 and LE3 are provided on the insulating layer 12 and are spaced apart from each other. The rib 5 is provided on the insulating layer 12 and the lower electrodes LE1 and LE3. The rib 5 is formed of an organic material or an inorganic material. The aperture AP1 overlaps the lower electrode LE1. The aperture AP3 overlaps the lower electrode LE3. The periphery of each of the lower electrodes LE1 and LE3 is covered by the rib 5. The insulating layer 12 is covered with the rib 5 between the lower electrodes LE1 and LE3. The lower electrodes LE1 and LE3 are connected to the pixel circuit 1 of each of the subpixels SP1 and SP3 through a contact hole provided in the insulating layer 12. The illustration of the contact hole of the insulating layer 12 is omitted in FIG. 4.

The common layer CL1 is provided on the lower electrodes LE1 and LE3 and the rib 5. In the illustrated example, the light emitting layer EM1 is located immediately above the lower electrode LE1 and is provided on the common layer CL1. The light emitting layer EM3 is located immediately above the lower electrode LE3 and is provided on the common layer CL1. The common layer CL2 is provided on the light emitting layers EM1 and EM3 and is provided on the common layer CL1 outside the light emitting layers EM1 and EM3. These common layer CL1, light emitting layer EM1, and common layer CL2 constitute the organic layer OR1 as explained with reference to FIG. 2. Similarly, these common layer CL1, light emitting layer EM3, and common layer CL2 constitute the organic layer OR3 as explained with reference to FIG. 2.

The upper electrode UE is provided on the common layer CL2. The upper electrode UE is formed of, for example, a metal material such as an alloy of magnesium and silver (MgAg).

The cap layer CP is provided on the upper electrode UE. The cap layer CP is a transparent multilayer body. The refractive indexes of the layers constituting the cap layer CP are different from one another. This cap layer CP functions as an optical adjustment layer for adjusting the optical property of a light beam emitted from the light emitting layers EM1 and EM3.

The sealing layer 16 is provided on the cap layer CP. The sealing layer 16 covers the display elements 201 and 203. The sealing layer 16 includes an organic layer which planarizes irregularities formed by the rib 5 and an inorganic layer protecting the light emitting layers EM1 and EM3 from moisture and the like.

The optical control element OD comprises the partitions P11, P12, and P13, a transparent optical layer OL1, and a plurality of light-shielding layers BM1 and BM2. The optical control element OD overlaps the sealing layer 16. In the illustrated example, the optical control element OD is provided on the sealing layer 16. The polarizer 17 is bonded to the upper surface of the optical control element OD through an adhesive AD.

The following describes the partition P12 among the partitions P11, P12, and P13. The partitions P11 and P13 have the same configuration as the partition P12.

The partition P12 has side surfaces S1 and S2, a bottom surface P12L, and an upper surface P12U. The side surface S1 of the partition P12 faces the partition P11 in the first direction X. The side surface S2 of the partition P12 faces the partition P13 in the first direction X. The bottom surface P12L faces the sealing layer 16 in the third direction Z. The upper surface P12U is located on a side opposite to the bottom surface P12L in the partition P12 and faces the polarizer 17 in the third direction Z. The side surfaces S1 and S2 of the partition 12 are inclined with respect to a normal 10N of the substrate 10 such that a width W12L of the bottom surface P12L is greater than a width W12U of the upper surface P12U (W12L>W12U). The width W12L is the length along the first direction X of the bottom surface P12L. The width W12U is the length along the first direction X of the upper surface P12U. That is, the partition P12 has a tapered cross section whose width along the first direction X decreases as the partition P12 extends from the sealing layer 16.

In the illustrated example, the optical layer OL1 is located between the pair of the partitions P11 and P12 adjacent to each other in the first direction X, and is in contact with the side surface S2 of the partition P11 and the side surface S1 of the partition P12. The optical layer OL1 is located between the pair of the partitions P12 and P13 adjacent to each other in the first direction X, and is in contact with the side surface S2 of the partition P12 and the side surface S1 of the partition P13. The optical layer OL1 overlaps the display elements 201 and 203 in the third direction Z. In the present embodiment, the optical layer OL1 surrounds the partitions P11, P12, and P13.

The partitions P11, P12, and P13 and the optical layer OL1 are formed of resin materials. The partitions P11, P12, and P13 are formed of materials that have refractive indexes smaller than the refractive index of the optical layer OL1. The partitions P11, P12, and P13 may be air layers. Each of the partitions P11, P12, and P13 may be transparent, colored, or a light absorbing body. The optical layer OL1 may have a function of bonding the sealing layer 16 and the polarizer 17 together.

The plurality of light-shielding layers BM1 (first light-shielding layers) are located between the sealing layer 16 and the respective partitions P11, P12, and P13. The plurality of the light-shielding layers BM1 overlap the respective partitions P11, P12, and P13. The optical layer OL1 surrounds the periphery of the light-shielding layer BM1.

A width WBM1 of the light-shielding layer BM1 is greater than a width W12L of the bottom surface P12L in the partition P12 (WBM1>W12L). That is, the light-shielding layer BM1 covers the entire bottom surface P12L. The width WBM1 is the length along the first direction X of the light-shielding layer BM1. The width WBM1 may be the same as the width W12L. The light-shielding layer BM1 overlapping each of the partitions P11 and P13 has the same shape as the light-shielding layer BM1 overlapping the partition P12.

A plurality of light-shielding layers BM2 (second light-shielding layers) are located between the polarizer 17 and the respective partitions P11, P12, and P13. The plurality of light-shielding layers BM2 overlap the respective partitions P11, P12, and P13. The optical layer OL1 surrounds the periphery of the light-shielding layer BM2.

A width WBM2 of the light-shielding layer BM2 is greater than the width W12U of the upper surface P12U in the partition P12 (WBM2>W12U). That is, the light-shielding layer BM2 covers the entire upper surface P12U. The width WBM2 is the length along the first direction X of the light-shielding layer BM2. The width WBM2 may be the same as the width W12U. The light-shielding layer BM1 overlapping each of the partitions P11 and P13 has the same shape as the light-shielding layer BM1 overlapping the partition P12.

In the illustrated example, the width WBM1 of the light-shielding layer BM1 is the same as the width WBM2 of the light-shielding layer BM2. The width WBM1 may be different from the width WBM2.

In the present embodiment, a refractive index of each of the partitions P11, P12, and P13 is smaller than a refractive index of the optical layer OL1. Therefore, for example, when an angle θ1 is smaller than the critical angle, a light beam L1 emitted from the light emitting layer EM1 and made incident on the side surface S1 of the partition P12 at the angle θ1 is subjected to total reflection on the side surface S1 of the partition P12. The light beam L1 totally reflected on the side surface S1 exits from the display device DSP to a direction close to the extending direction (the third direction Z) of the normal 10N of the substrate 10. Thus, a light beam emitted from the light emitting layer is visually recognizable in a case where the display device DSP is seen from the front position. In contrast, a light beam emitted from the light emitting layer is hard to visually recognize when the display device DSP is obliquely seen from the first direction X side. Therefore, the viewing angle of the pixel PX1 can be limited.

A refractive index difference between the refractive index of the partition and that of the optical layer is preferably 0.2 or more for totally reflecting light beams at the boundary between the partition and the optical layer. As an example, the refractive index of the partition is 1.25, and the refractive index of the optical layer is 1.5.

When the partition is formed of the light absorbing body, among light beams emitted from the light emitting layer, light beams emitted toward the direction close to the extending direction of the normal 10N are visually recognizable. The other light beams are absorbed by the partition, which is the light absorbing body, and thus are hard to visually recognize. Therefore, in this case, the viewing angle of the pixel PX1 can be limited.

A refractive index of the optical layer OL1 is preferably equivalent to a refractive index of the sealing layer 16. For example, when the refractive index of the optical layer OL1 is smaller than the refractive index of the sealing layer 16, light beams emitted from the light emitting layer are refracted at the boundary between the optical layer OL1 and the sealing layer 16. Thus, many light beams are made incident on the partition at angles greater than the critical angle. The light beams made incident at the angles greater than the critical angle pass through the partition without being reflected on the side surface of the partition. Thus, few light beams are emitted toward the direction close to the extending direction of the normal 10N. Therefore, the luminance of a displayed image in a case where the display device DSP is seen from the front position may decrease. In contrast, when the refractive index of the optical layer OL1 and the refractive index of the sealing layer 16 are equivalent or almost equivalent to each other, the light beams emitted from the light emitting layer travel straight substantially without being refracted at the boundary between the sealing layer 16 and the optical layer OL1. Therefore, many light beams are made incident on the partition at angles smaller than the critical angle and are reflected on the side surface of the partition. This may suppress the decrease in the luminance of a displayed image in a case where the display device DSP is seen from the front position.

In the display device DSP of the present embodiment, the optical control element OD comprises the light-shielding layers BM1 and BM2. As shown in FIG. 4 as an example, the light-shielding layers BM1 and BM2 have the function of absorbing a light beam L2 emitted from the light emitting layer EM1 toward the bottom surface P12L of the partition P12. If there are no light-shielding layers, the light beam L2 is made incident on the bottom surface P12L and passes through the partition P12, and mixes with the light beam emitted from the light emitting layer EM3. This may cause color mixture. The optical control element OD comprising the light-shielding layers BM1 and BM2 can prevent the color mixture and thus suppress the degradation in display quality.

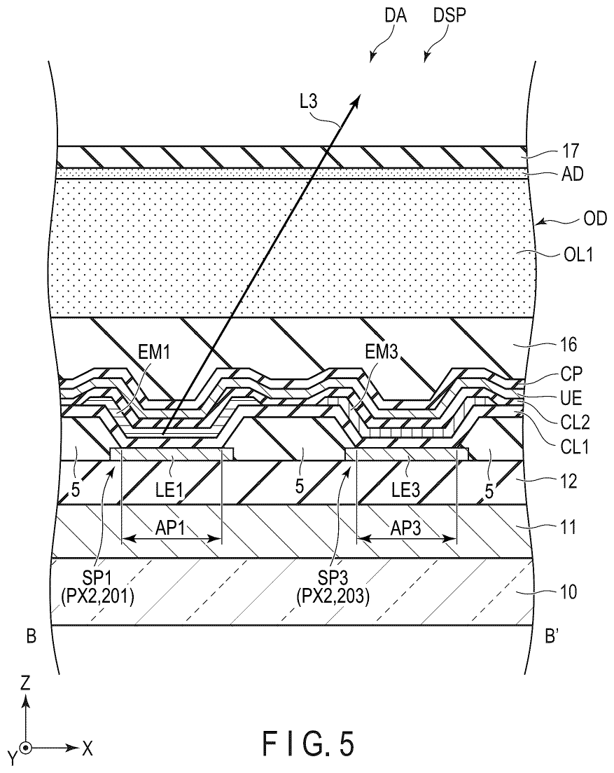

FIG. 5 is a cross-sectional view showing the configuration example of the display device DSP along line B-B′ in FIG. 3.

The optical layer OL1 overlaps the display elements 201 and 203 of the pixel PX2 in the third direction Z. In the illustrated example, the optical layer OL1 is provided on the sealing layer 16. In this manner, among the optical control elements OD, the optical layer OL1 overlaps the pixel PX2, but the partition does not overlap the pixel PX2. For example, a light beam L3 emitted from the light emitting layer EM1 travels straight without being reflected at the optical control element OD. Therefore, a broad angle is achieved in the pixel PX2, compared to that in the pixel PX1.

As shown in FIG. 3, in the present embodiment, the pixel PX1 overlapping the partition and the pixel PX2 not overlapping the pixel are alternately arranged along the second direction Y. As shown in FIG. 4, light beams emitted from the light emitting layer in the pixel PX1 are reflected on the side surface of the partition and then are guided to the direction close to the extending direction (the third direction Z) of the normal 10N. In contrast, as shown in FIG. 5, the light beams emitted from the light emitting layer pass through the optical control element OD in the pixel PX2. In this configuration, a case where the pixel PX1 is illuminated and the pixel PX2 is not illuminated is referred to as a first mode. In the first mode, an image displayed in the display area DA is visually recognizable when the display device DSP is seen from the front position, in contrast, the image is hard to visually recognize when the display device DSP is obliquely seen from the first direction X side. A case where the pixel PX1 is not illuminated but the pixel PX2 is illuminated and a case where both of the pixels PX1 and PX2 are illuminated are referred to as a second mode. In the second mode, an image displayed is visually recognizable when the display device DSP is seen from the front or is obliquely seen from the first direction X side.

The following describes a case where the display device DSP of the present embodiment is mounted on a vehicle such as an automobile. The display device DSP is assumed to be mounted in front of a passenger seat. For example, at the time of driving, it is required that an image displayed on the display device DSP is hard to visually recognize from a side of a driver seat and, in contrast, this image is visually recognizable from a passenger seat. In this case, an image is displayed in the first mode. Thus, the visual recognition of an image is limited from the side of the driver seat. In contrast, the image is sufficiently visually recognizable from the side of the passenger seat. In contrast, an image is displayed in the second mode when the following case is required: an image is visually recognizable from both of the side of the driver seat and the side of the passenger seat while engine is in off state. Thus, an image is sufficiently visually recognizable from both of the side of the driver seat and the side of the passenger seat. By switching the first mode and the second mode in this manner, the viewing angle is controlled. Thus, the visibility of an image from, particularly, the side of the driver seat can be switched.

In the above examples, for example, each of the display elements 201, 202, and 203 of the pixel PX1 corresponds to the first display element, each of the display elements 201, 202, and 203 of the pixel PX2 corresponds to the second display element, and each of the partitions P11, P12, and 13 corresponds to the first partition. When the display element 201 of the pixel PX1 corresponds to the first display element, the partitions P11 and P12 correspond to a pair of the first partitions. When the display element 202 or the display element 203 of the pixel PX1 corresponds to the first display element, the partitions P12 and P13 correspond to a pair of the first partitions.

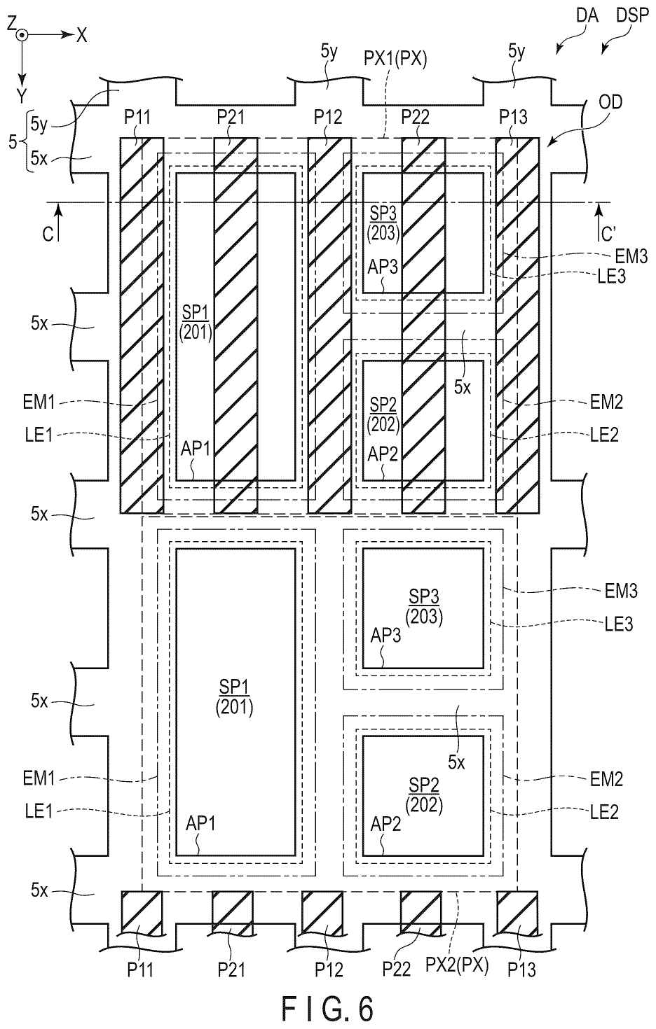

FIG. 6 is a view showing another configuration example of the surroundings of the pixels PX of the first embodiment. The elements equivalent to or similar to the abode-described elements are denoted by the same reference numbers and overlapping descriptions of these elements are omitted.

The optical control element OD further includes partitions P21 and P22. The partitions P21 and P22 extend in the second direction Y. The partition P21 is located between the partition P11 and the partition P12 and overlaps the display element 201 in the third direction Z. The partition P22 is located between the partition P12 and the partition P13 and overlaps the display elements 202 and 203 in the third direction Z. The partitions P21 and P22 overlap the pixel PX1 in the third direction Z but do not overlap the pixel PX2.

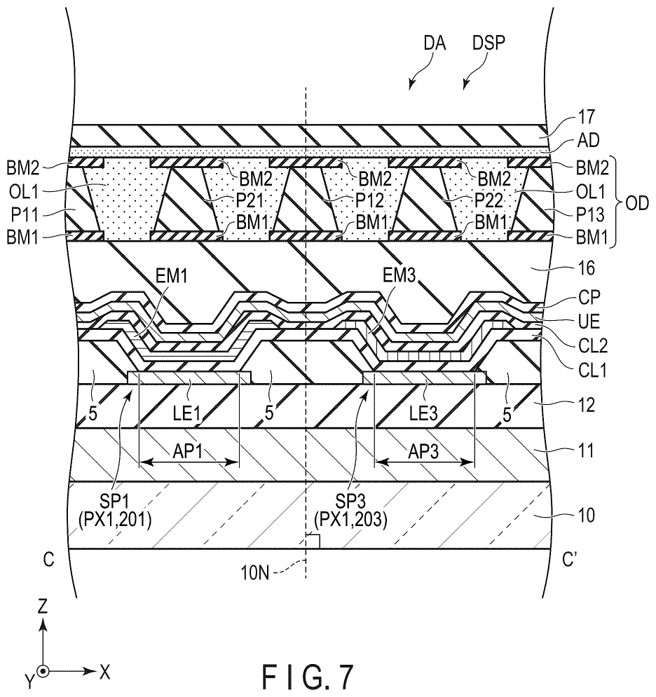

FIG. 7 is a cross-sectional view showing the configuration example of the display device DSP along line C-C′ in FIG. 6. The partitions P21 and P22 have the same shape of the partitions P11, P12, and P13.

The number of partitions overlapping one pixel in the display device DSP shown in FIG. 6 and FIG. 7 is greater than that of the display device DSP shown in FIG. 3 and FIG. 4. The increase in the number of the partitions overlapping one pixel increases the number of light beams reflected on the partition, among the light beams emitted from the light emitting layer, and restricts light beams passing through a space between adjacent partitions. Therefore, the increase in the number of the partitions further limits the viewing angle.

In contrast, the decrease in the height of the partitions decreases the number of light beams reflected on the partition, among the light beams emitted from the light emitting layer. This broadens the viewing angle. Further, the decrease in the height of the partition achieves a thinner display device DSP.

That is, the increases in the number of the partitions overlapping one pixel and the decrease in the height of the partition achieves a thinner display device DSP having the viewing angle almost equivalent to the display device DSP shown in FIG. 3 and FIG. 4. In the display device DSP shown in FIG. 6 and FIG. 7 as well, the increases in the number of the partitions overlapping one pixel and the decrease in the height of the partition achieves a thinner display device DSP having the viewing angle almost equivalent to the display device DSP shown in FIG. 3 and FIG. 4.

In the above example, for example, the partitions P11, P12, and P13 correspond to the first partition, and the partitions P21 and P22 correspond to the second partition. When the display element 201 of the pixel PX1 corresponds to the first display element, the partitions P11 and P12 correspond to a pair of the first partitions, and the partition P21 corresponds to the second partition. When the display element 202 or the display element 203 of the pixel PX1 corresponds to the first display element, the partitions P12 and P13 correspond to the first partition, and the partition P22 corresponds to the second partition.

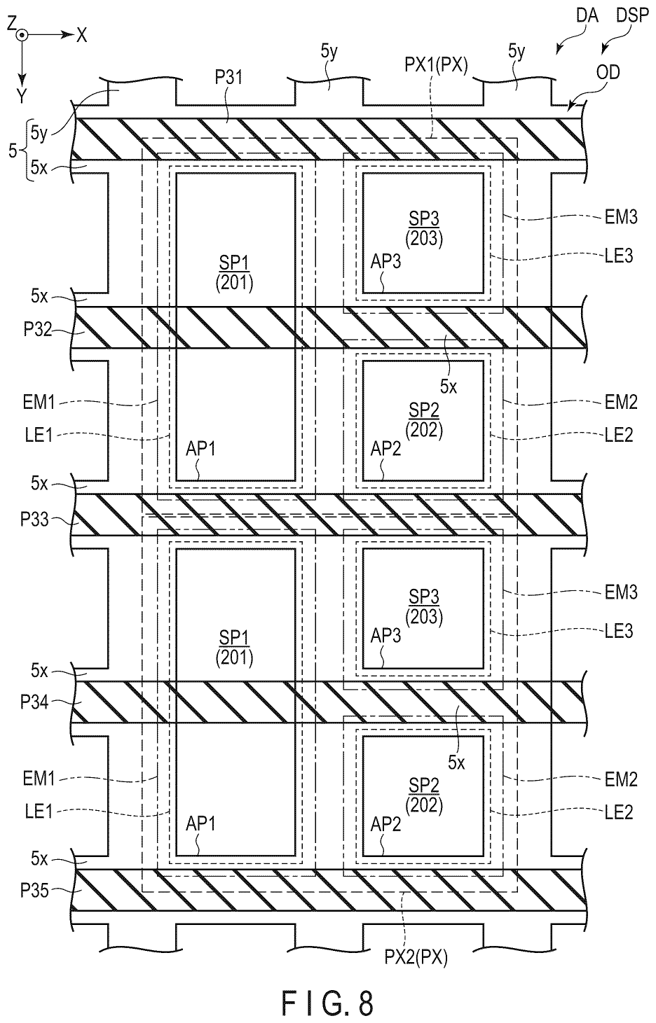

FIG. 8 is a view showing yet another configuration example of the surroundings of the pixels PX of the first embodiment. The display device DSP shown in FIG. 8 is different from the display device DSP shown in FIG. 3 in comprising partitions P31 to P35 instead of the partitions P11, P12, and P13 shown in FIG. 3.

The optical control element OD includes the partitions P31 to P35. Each of the partitions P31 to P35 extends in the first direction X. Each of the partitions P31, P33, and P35 are located between the pixels PX1 and PX2 adjacent to each other in the second direction Y.

The partition P32 is located between the partition P31 and the partition P33 and overlaps the display element 201 of the pixel PX1 in the third direction Z. The partition P32 is located between the display element 202 and the display element 203 of the pixel PX1 in the second direction Y. The partition P34 is located between the partition P33 and the partition P35 and overlaps the display element 201 of the pixel PX2 in the third direction Z. The partition P34 is located between the display element 202 and the display element 203 of the pixel PX2 in the second direction Y. The partitions P31 to P35 overlap the rib 5 in the third direction Z.

The partitions P31 to P33 sandwich the display element 201 of the pixel PX1 along the second direction Y in plan view. The partitions P32 and P33 sandwich the display element 202 of the pixel PX1 along the second direction Y in plan view. The partitions P31 and P32 sandwich the display element 203 of the pixel PX1 along the second direction Y in plan view. The partitions P33 and P35 sandwich the display element 201 of the pixel PX2 along the second direction Y in plan view. The partitions P34 and P35 sandwich the display element 202 of the pixel PX2 along the second direction Y in plan view. The partitions P33 and P34 sandwich the display element 203 of the pixel PX2 along the second direction Y in plan view.

The light beams emitted from the light emitting layer are reflected on the side surface of each of the partitions P31 to P35 and travel in the direction close to the third direction Z. In the display device DSP shown in FIG. 3, an image is hard to visually recognize when the display device DSP is obliquely seen from the first direction X side. In contrast, in the display device DSP shown in FIG. 8, an image is hard to visually recognize when the display device DSP is obliquely seen from the second direction Y side.

In the display device DSP shown in FIG. 8, when the display device DSP of the present embodiment is mounted on a vehicle such as an automobile, an undesirable reflection of an image displayed in the display area DA onto the front window of the automobile can be suppressed.

In the above example, for example, when the display element 201 of the pixel PX1 corresponds to the first display element, the partitions P31 and P33 correspond to a pair of the first partitions, and the partition P32 corresponds to the second partition. When the display element 202 of the pixel PX1 corresponds to the first display element, a pair of the partitions P32 and P33 corresponds to a pair of the first partitions. When the display element 203 of the pixel PX1 corresponds to the first display element, a pair of the partitions P31 and P32 corresponds to a pair of the first partitions.

When the display element 201 of the pixel PX2 corresponds to the first display element, the partitions P33 and P35 correspond to a pair of the first partitions, and the partition P34 corresponds to the second partition. When the display element 202 of the pixel PX2 corresponds to the first display element, the partitions P34 and P35 correspond to a pair of the first partitions. When the display element 203 of the pixel PX2 corresponds to the first display element, the partitions P33 and P34 correspond to a pair of the first partitions.

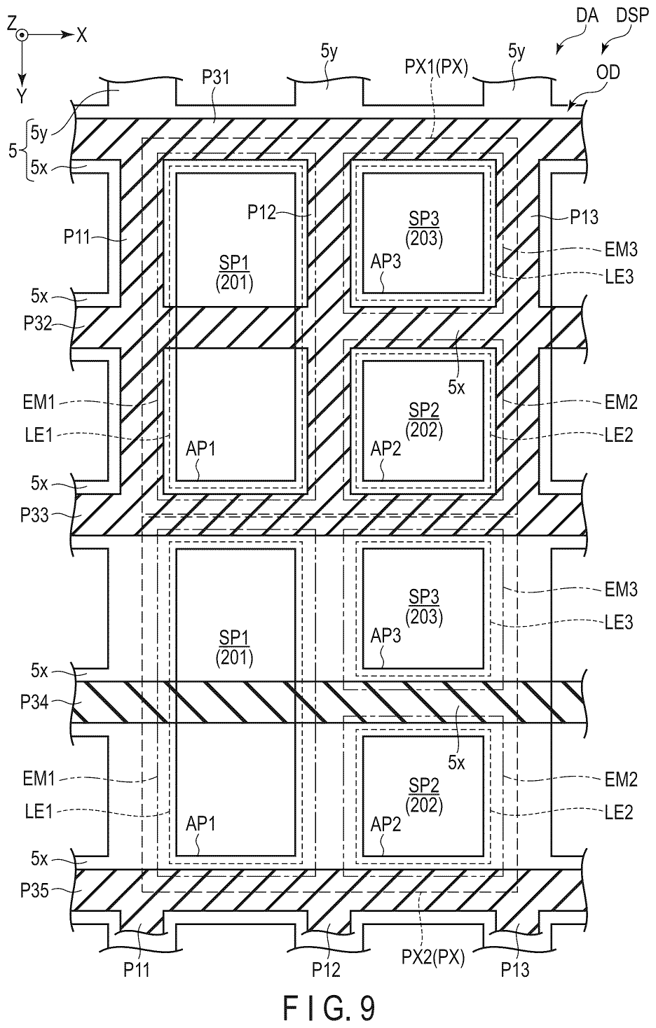

FIG. 9 is a view showing yet another configuration example of the surroundings of the pixels PX of the first embodiment. The display device DSP shown in FIG. 9 comprises a partition corresponding to the combination of the partitions P11, P12, and P13 shown in FIG. 3 and the partitions P31 to P35 shown in FIG. 8.

Each of the partitions P31, P32, P33, and P35 intersects all of the partitions P11, P12, and P13. In the example of FIG. 9, the partitions P11, P12, and P13 and the partitions P31, P32, and P33 are connected to each other. The partitions P11, P12, P13, and P35 are connected to one another. In the pixel PX1, the display element 201 is surrounded by the partitions P11, P12, P31, and P33. In the pixel PX1, the display element 202 is surrounded by the partitions P12, P13, P32, and P33. In the pixel PX1, the display element 203 is surrounded by the partitions P12, P13, P31, and P32.

In the display device DSP shown in FIG. 9, switching the first mode and the second mode varies the viewing angle in the first direction X and also narrows the viewing angle in the second direction Y.

In the above example, for example, when the display element 201 of the pixel PX1 corresponds to the first display element, the partitions P31 and P33 correspond to a pair of the first partitions, the partition P32 corresponds to the second partition, and the partitions P11 and P12 correspond to a pair of the third partitions. When the display element 202 of the pixel PX1 corresponds to the first display element, the partitions P32 and P33 correspond to a pair of the first partitions, and the partitions P12 and P13 correspond to a pair of the third partitions. When the display element 203 of the pixel PX1 corresponds to the first display element, the partitions P31 and P32 correspond to a pair of the first partitions, and the partitions P12 and P13 correspond to a pair of the third partitions.

When the display element 201 of the pixel PX2 corresponds to the first display element, the partitions P33 and P35 correspond to a pair of the first partitions, and the partition P34 corresponds to the second partition. When the display element 202 of the pixel PX2 corresponds to the first display element, the partitions P34 and P35 correspond to a pair of the first partitions. When the display element 203 of the pixel PX2 corresponds to the first display element, the partitions P33 and P34 correspond to a pair of the first partitions.

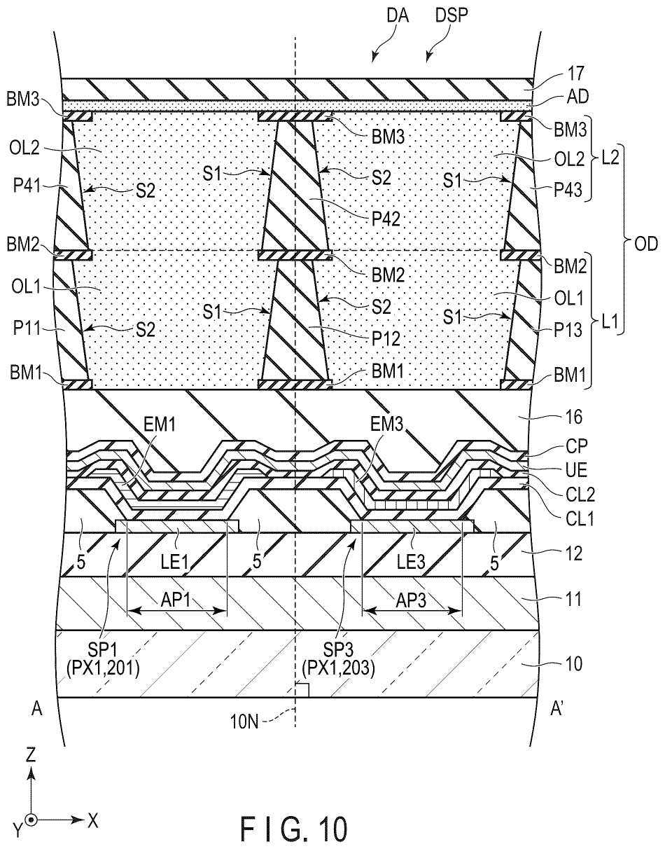

FIG. 10 is a cross-sectional view showing another configuration example of the display device DSP along line A-A′ in FIG. 3. The display device DSP shown in FIG. 10 is different from the display device DSP shown in FIG. 4 in the point that the optical control element OD is formed as a multilayer body.

The optical control element OD comprises a first layer L1 and a second layer L2. The second layer L2 is provided on the first layer L1 in the third direction Z. Similarly to the example shown in FIG. 4, the first layer L1 comprises the partitions P11, P12, and P13, the optical layer OL1, the light-shielding layer BM1, and the light-shielding layer BM2. The second layer L2 comprises partitions P41, P42, and P43, an optical layer OL2, and a plurality of light-shielding layers BM3.

The partition P41 overlaps the partition P11. In the illustrated example, the partition P41 is located directly above the partition P11. The partition P42 overlaps the partition P12. In the illustrated example, the partition P42 is located directly above the partition P12. The partition P43 overlaps the partition P13. In the illustrated example, the partition P43 is located directly above the partition P13. The partitions P41, P42, and P43 are located on the light-shielding layer BM2.

In the illustrated example, the partitions P41, P42, and P43 have the same shape and the size as the partitions P11, P12, and P13. Similarly to the partitions P11, P12, and P13, each of the partitions P41, P42, and P43 has the side surfaces S1 and S2 inclined with respect to the normal 10N of the substrate 10.

The optical layer OL2 is located between the pair of the partitions P41 and P42 adjacent to each other in the first direction X, and is in contact with the side surface S2 of the partition P41 and the side surface S1 of the partition P42. The optical layer OL2 is located between the pair of the partitions P42 and P43 adjacent to each other in the first direction X, and is in contact with the side surface S2 of the partition P42 and the side surface S1 of the partition P43. The optical layer OL2 overlaps the display elements 201 and 203 in the third direction Z and is provided on the optical layer OL1. In the present embodiment, the optical layer OL2 surrounds the partitions P41, P42, and P43.

A plurality of light-shielding layers BM3 are located between the polarizer 17 and the respective partitions P41, P42, and P43. The plurality of light-shielding layers BM3 overlap the respective partitions P41, P42, and P43. The plurality of light-shielding layers BM3 cover the upper surface of the respective partitions P41, P42, and P43. The periphery of the light-shielding layer BM3 is covered with the optical layer OL2.

The optical control element OD shown in FIG. 10 is formed as a multilayer body of two layers. Thus, the height of the partition shown in FIG. 10 is higher than the height of the partition shown in FIG. 4. The increase in the height of the partition increases the number of light beams reflected on the partition, among the light beams emitted from the light emitting layer, and further limits the viewing angle. Therefore, the display device DSP shown in FIG. 10 can limit the viewing angle more than the display device DSP shown in FIG. 4 does.

Even when the optical control element is formed as a single-layer body, the increase in the height of the partition can narrow the viewing angle. However, the increase in the height of the partition with maintaining the inclination angle of the side surface of the partition increases the width of the bottom surface of the partition. Therefore, the width of the light-shielding layer covering the bottom surface of the partition increases. This may decrease the luminance of the displayed image. The higher the height of the partition, more difficult processing of the partition.

In contrast, the width of the bottom surface of the partition can be small in a case where the optical control element is formed as the multilayer body, compared to the case where the optical control element is formed of a single-layer body. This can decrease the width of the light-shielding layer covering the bottom surface of the partition and suppress the decrease in the luminance of the displayed image. The height of each of the partitions in the case where the optical control element is formed as the multilayer body is lower than that of the case where the optical control element is formed as a single-layer body. Therefore, processing of the partition is relatively easy in the former case.

The optical control element OD may be formed as a multilayer body consisting more than three layers.

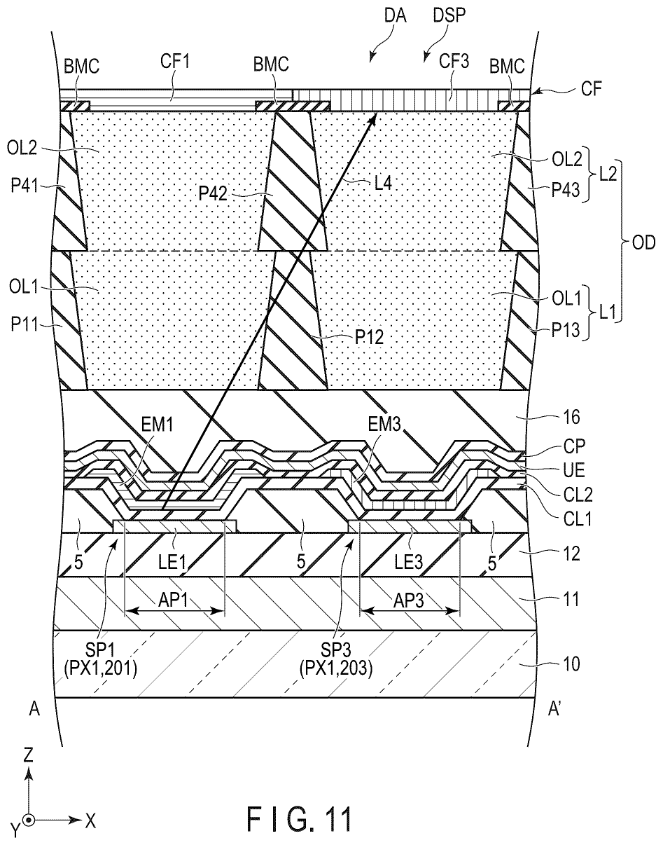

FIG. 11 is a cross-sectional view showing yet another configuration example of the display device DSP along line A-A′ in FIG. 3. The display device DSP shown in FIG. 11 is different from the display device DSP shown in FIG. 10 in comprising none of the light-shielding layers BM1, BM2, and BM3 and comprising a color filter layer CF and a light-shielding layer BMC instead of the polarizer 17.

The partitions P11, P12, and P13 are provided on the sealing layer 16. The partition P41 is provided on the partition P11. The partition P42 is provided on the partition P12. The partition P43 is provided on the partition P13.

The color filter layer CF is provided on the optical control element OD. The color filter layer CF includes a color filter CF1 formed of a blue-colored resin material and a color filter CF3 formed of a red-colored resin material. The color filter CF1 overlaps the display element 201. The color filter CF3 overlaps the display element 203. Though not illustrated, the color filter layer CF includes a color filter formed of a green-colored resin material and overlapping the display element 202 shown in FIG. 3.

The light-shielding layer BMC is provided between color filters of colors different from each other. In the example of FIG. 11, the light-shielding layer BMC is located between the color filter CF1 and the color filter CF3 and between the optical control element OD and the color filter layer CF.

Depending on angles of emission, a light beam emitted from the light emitting layer EM1 may pass through the partitions P12 and P42 without being reflected on the partition 12, as a light beam L4. If there are no color filter layers CF, the blue-colored light beam L4 emitted from the light emitting layer EM1 and a red-colored light beam emitted from the light emitting layer EM3 mix with each other. This may cause the degradation in display quality.

The display device DSP shown in FIG. 11 comprises the color filter layer CF. Thus, the blue-colored light beam L4 emitted from the light emitting layer EM1 is absorbed by the red color filter layer CF3. This can prevent the occurrence of color mixture and thus suppress the degradation in display quality.

The color filter layer CF has the function of suppressing the degradation in display quality caused by reflection of external light. Therefore, a display device DSP that comprises the color filter layer CF may not comprise a polarizer. If it is the case, the display device DSP has no polarizer and thus can improve the luminance of the display device DSP.

The optical control element OD shown in FIG. 11 is formed as the multilayer body of two layers. This optical control element OD may be formed as a single-layer body or a multilayer body of three or more layers.

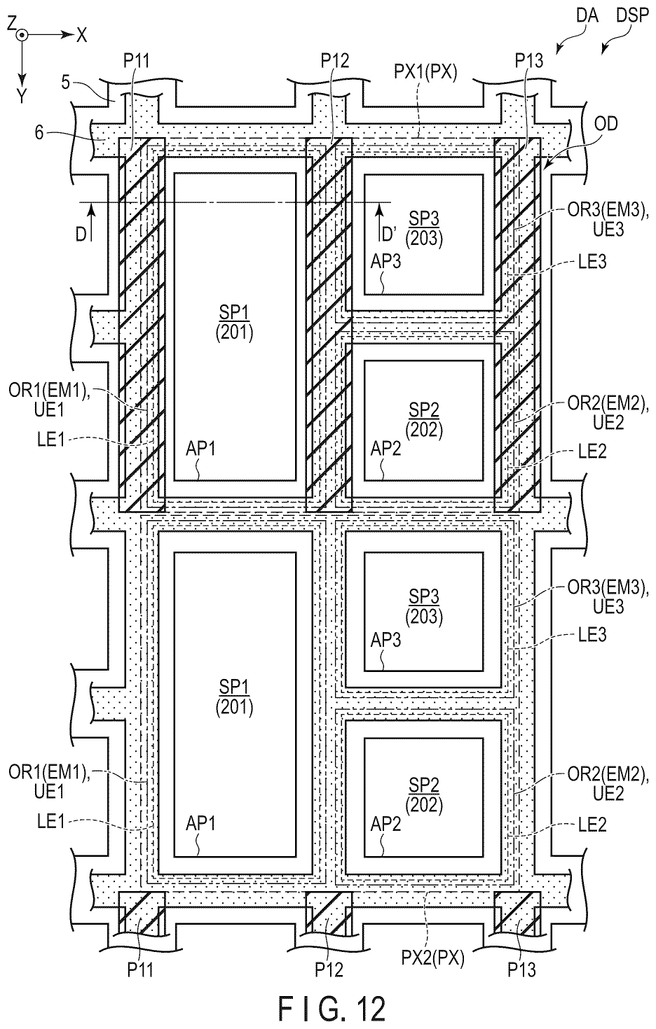

FIG. 12 is a view showing yet another configuration example of the surroundings of the pixels PX of the first embodiment.

The partition 6 is provided in the display area DA. The partition 6 overlaps the rib 5 in plan view. The partition 6 is formed into a grating shape surrounding the apertures AP1, AP2, and AP3. That is, the partition 6 includes apertures in the subpixels SP1, SP2, and SP3, similarly to the rib 5. The partition 6 is conductive and is electrically connected to a terminal having a common potential, among a plurality of terminals provided in the surrounding area SA shown in FIG. 1.

The display element 201 of the subpixel SP1 comprises the lower electrode LE1, the organic layer OR1 (the light emitting layer EM1), and the upper electrode UE1 overlapping the aperture AP1.

The display element 202 of the subpixel SP2 comprises the lower electrode LE2, the organic layer OR2 (the light emitting layer EM2), and the upper electrode UE2 overlapping the aperture AP2.

The display element 203 of the subpixel SP3 comprises the lower electrode LE3, the organic layer OR3 (the light emitting layer EM3), and the upper electrode UE3 overlapping the aperture AP3.

Each of the display elements 201, 202, and 203 is surrounded by the partition 6 in plan view.

In the example of FIG. 12, the outer shapes of the lower electrodes LE1, LE2, and LE3 are indicated by dotted lines, and the outer shapes of the organic layers OR1, OR2, and OR3 and the upper electrodes UE1, UE2, and UE3 are indicated by two-dot chain line. The outer shape of each of the lower electrodes, organic layers, and upper electrodes shown in the figure does not necessarily reflect the accurate shape.

For example, the lower electrodes LE1, LE2, and LE3 correspond to the anodes of the display elements. The upper electrodes UE1, UE2, and UE3 correspond to the cathodes of the display elements or a common electrode and are in contact with the partition 6.

The partitions P11, P12, and P13 overlap the partition 6 located in the pixel PX1 in the third direction Z. In the illustrated example, in the pixel PX1, the partition P11 overlaps the periphery of each of the lower electrode LE1, the organic layer OR1, and the upper electrode UE1 in the third direction Z. In the pixel PX1, the partition P12 overlaps the periphery of each of the lower electrodes LE1, LE2, and LE3, the organic layers OR1, OR2, and OR3, and the upper electrodes UE1, UE2, and UE3 in the third direction Z. In the pixel PX1, the partition P13 overlaps the periphery of each of the lower electrodes LE2 and LE3, the organic layers OR2 and OR3, and the upper electrodes UE2 and UE3 in the third direction Z.

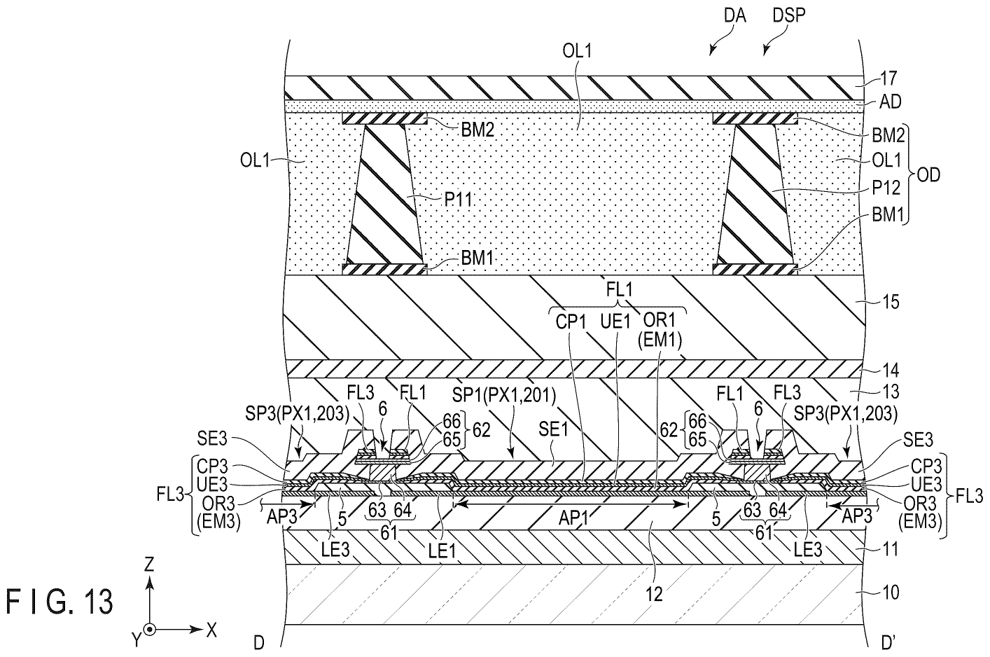

FIG. 13 is a cross-sectional view showing the configuration example of the display device DSP along line D-D′ in FIG. 12. The following describes the display elements 201 and 203 among the display elements 201, 202, and 203 of the pixel PX1. Note that the display element 202 has the same cross section of each of the display elements 201 and 203.

The partition 6 includes a conductive lower portion 61 provided on the rib 5 and an upper portion 62 provided on the lower portion 61. The both end portions of the upper portion 62 project relative to the side surfaces of the lower portion 61. This shape of the partition 6 is called an overhang shape.

In the illustrated example, the lower portion 61 includes a first conductive layer 63 provided on the rib 5 and a second conductive layer 64 provided on the first conductive layer 63. For example, the first conductive layer 63 is thinner than the second conductive layer 64. Further, in the illustrated example, the both end portions of the first conductive layer 63 project relative to the respective side surfaces of the second conductive layer 64.

The upper portion 62 includes a thin film 65 provided on the second conductive layer 64 and a thin film 66 provided on the thin film 65. The both end portions of each of the thin film 65 and the thin film 66 project relative to the respective side surfaces of the second conductive layer 64.

The organic layer OR1 is in contact with the lower electrode LE1 through the aperture AP1 and covers the lower electrode LE1 exposed from the aperture AP1. The periphery of the organic layer OR1 is located on the rib 5. The upper electrode UE1 covers the organic layer OR1 and is in contact with the lower portion 61.

The organic layer OR3 is in contact with the lower electrode LE3 through the aperture AP3 and covers the lower electrode LE3 exposed from the aperture AP3. The periphery of the organic layer OR3 is located on the rib 5. The upper electrode UE3 covers the organic layer OR3 and is in contact with the lower portion 61.

In the example of FIG. 13, the subpixel SP1 includes the cap layer CP1 and the sealing layer SE1. The subpixel SP3 includes a cap layer CP3 and a sealing layer SE3. The cap layers CP1 and CP3 function as optical adjustment layers which improve the extraction efficiency of a light beam emitted from the respective organic layers OR1 and OR3. The cap layers CP1 and CP3 may be omitted.

The cap layer CP1 is provided on the upper electrode UE1.

The cap layer CP3 is provided on the upper electrode UE3.

The sealing layer SE1 is provided on the cap layer CP1, is in contact with the partition 6, and continuously covers each member of the subpixel SP1.

The sealing layer SE3 is provided on the cap layer CP3, is in contact with the partition 6, and continuously covers each member of the subpixel SP3.

In the example of FIG. 13, portions of the organic layer OR1, the upper electrode UE1, and the cap layer CP1 are located on the partition 6 around the subpixel SP1. These portions are spaced apart from portions located in the aperture AP1 (the portions constituting the display element 201) of the organic layer OR1, the upper electrode UE1, and the cap layer CP1.

Similarly, portions of the organic layer OR3, the upper electrode UE3, and the cap layer CP3 are located on the partition 6 around the subpixel SP3. These portions are spaced apart from the portions located in the aperture AP3 (the portions constituting the display element 203) of the organic layer OR3, the upper electrode UE3, and the cap layer CP3.

In the following explanation, a multilayer body including the organic layer OR1, the upper electrode UE1, and the cap layer CP1 is called a stacked film FL1. A multilayer body including the organic layer OR3, the upper electrode UE3, and the cap layer CP3 is called a stacked film FL3.

The end portions of each of the sealing layers SE1 and SE3 and the end portions of each of the stacked films FL1 and FL3 are located on the partition 6. In the example of FIG. 13, the stacked film FL1 and the sealing layer SE1 located on the partition 6 between the subpixels SP1 and SP3 are spaced apart from the stacked film FL3 and the sealing layer SE3 located on this partition 6.

The partition 6 and the sealing layers SE1 and SE3 are covered by the resin layer 13. The resin layer 13 is covered with the sealing layer 14. The sealing layer 14 is covered with the resin layer 15.

The sealing layers SE1 and SE3 and the sealing layer 14 are formed of inorganic insulating materials.

The lower portion 61 of the partition 6 is formed of a conductive material and is electrically connected to the upper electrodes UE1 and UE3.

The upper portion 62 of the partition 6 is formed of, for example, a conductive material. The upper portion 62 may be formed of an insulating material.

The optical control element OD is provided on the resin layer 15. The partitions P11 and P12, the plurality of light-shielding layers BM1, and the plurality of light-shielding layers BM2 are provided directly above the partition 6.

The display device DSP of FIG. 12 and FIG. 13 can achieve advantages equivalent to the above advantages.

FIG. 14 is a view showing yet another configuration example of the surroundings of the pixels PX of the first embodiment. The display device DSP shown in FIG. 14 is different from the display device DSP shown in FIG. 3 in the layout of the subpixels SP1, SP2, and SP3.

In the example of FIG. 14, the subpixels SP1, SP2, and SP3 are arranged in the first direction X. The subpixels SP1 and SP3 sandwich the subpixel SP2 along the first direction X. Each of the apertures AP1, AP2, and AP3 has a rectangular shape having long sides parallel to the second direction Y. In the example of FIG. 14, the pixel apertures AP1, AP2, and AP3 have the same area.

The optical control element OD comprises a partition P14 in addition to the partitions P11, P12, and P13. The partition P14 has the same configuration as the partitions P11, P12, and P13. The partitions P11 and P12 sandwich the display element 203 of the pixel PX1 along the first direction X in plan view. The partitions P12 and P13 sandwich the display element 202 of the pixel PX1 along the first direction X in plan view. The partitions P13 and P14 sandwich the display element 201 of the pixel PX1 along the first direction X in plan view.

The display device DSP shown in FIG. 14 can exhibit the same effects as those achieved by the display device DSP shown in FIG. 3. Not only the examples shown in FIG. 3 and FIG. 14 but various layouts may be adopted as the layout of the subpixels SP1, SP2, and SP3.

### Second Embodiment

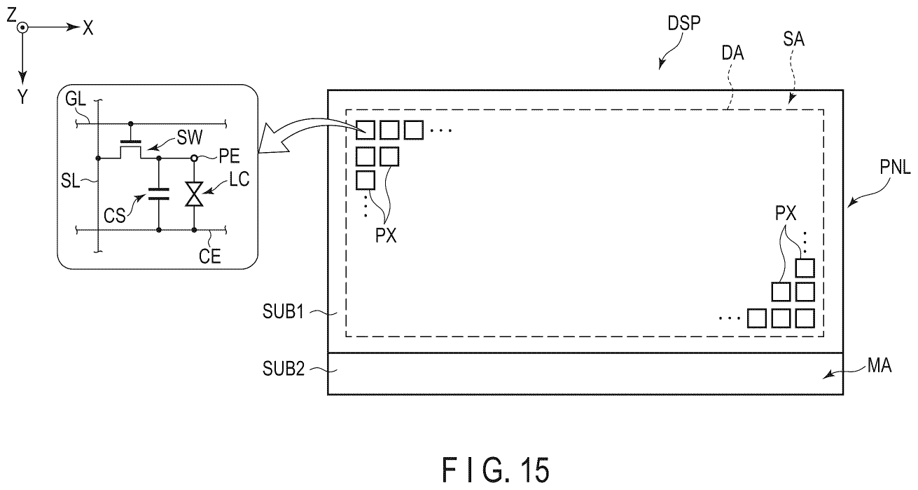

FIG. 15 is a view showing a configuration example of a display device DSP of the second embodiment. The display device DSP of the present embodiment is a liquid crystal display device, and can be mounted on televisions, personal computers, vehicle-mounted devices, tablet terminals, smartphones, mobile phones, and the like. The specification describes a display device mounted on a vehicle such as an automobile as an example. The same elements as those of the display device DSP of the first embodiment are denoted by the same reference numbers and overlapping descriptions of these elements are omitted.

The display device DSP comprises a display panel PNL including: a first substrate SUB1; a second substrate SUB2 facing the first substrate SUB1 in the third direction Z; and a liquid crystal layer LC enclosed between the first substrate SUB1 and the second substrate SUB2. In the illustrated example, each of the first substrate SUB1 and the second substrate SUB2 has a rectangular shape having long sides parallel to the first direction X in plan view. The shapes of the first substrate SUB1 and the second substrate SUB2 are not limited to this example. For example, the first substrate SUB1 and the second substrate SUB2 may have shapes such as a rectangular shape having long sides parallel to the second direction Y, a circular shape, and an elliptic shape.

The width of the first substrate SUB1 in the second direction Y is greater than the width of the second substrate SUB2 in the second direction Y. Thus, the first substrate SUB1 has a mounting area MA, which does not overlap the second substrate SUB2. In the mounting area MA, integrated circuits and flexible printed circuits (not shown) are mounted.

The display panel PNL includes a display area DA which displays an image and a surrounding area SA having a frame shape surrounding the display area DA. Both of the display area DA and the surrounding area SA are formed on portions on which the first substrate SUB1 overlaps the second substrate SUB2. The display area DA comprises a plurality of pixels PX arranged in a matrix in the first direction X and the second direction Y.

As shown in the enlarged manner in FIG. 15, a plurality of scanning lines GL and a plurality of signal lines SL are provided in the display area DA. The plurality of scanning lines GL extend in the first direction X and are arranged in the second direction Y. The plurality of signal lines SL extend in the second direction Y and are arranged in the first direction X. The plurality of signal lines SL intersect the plurality of scanning lines GL.

Each pixel PX comprises a switching element SW, a pixel electrode PE, a common electrode CE, and a capacity CS. The switching element SW is constituted by, for example, a thin-film transistor (TFT) and is electrically connected to the scanning line GL and the signal line SL. The pixel electrode PE is electrically connected to the switching element SW.

A liquid crystal layer LC is driven by an electric field generated between the pixel electrode PE and the common electrode CE. The capacitor CS is formed, for example, between an electrode having the same electric potential as the common electrode CE and an electrode having the same potential as the pixel electrode PE.

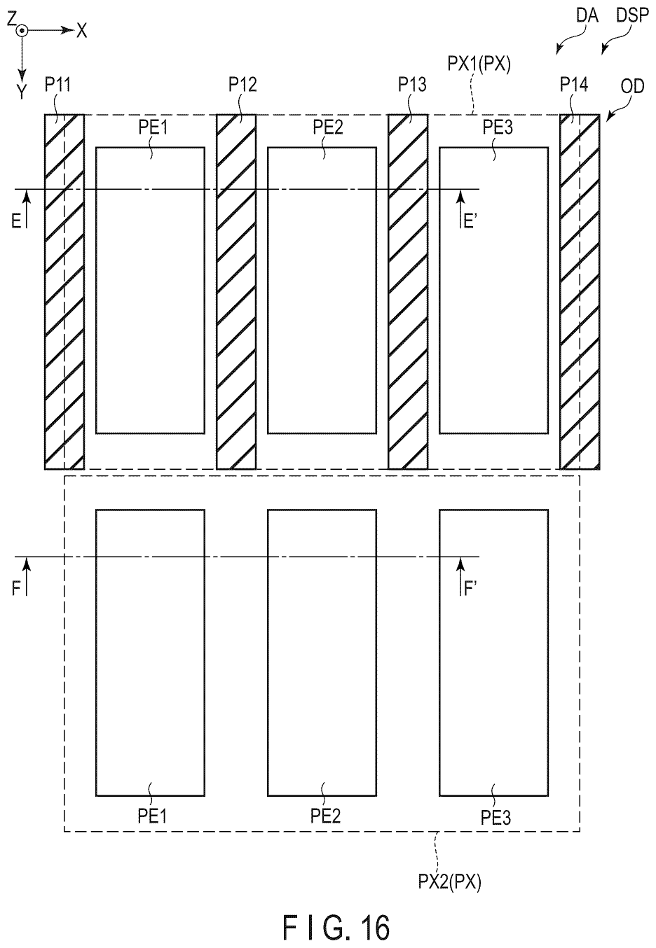

FIG. 16 is a view showing a configuration example of surroundings of pixels PX of the second embodiment. Each of the pixels PX1 and PX2 comprises pixel electrodes PE1, PE2, and PE3 as pixel electrodes PE shown in FIG. 15.

In the example of FIG. 16, the pixel electrodes PE1, PE2, and PE3 are arranged in the first direction X. The pixel electrode PE1 and the pixel electrode PE3 sandwich the pixel electrode PE2 along the first direction X. Each of the pixel electrodes PE1, PE2, and PE3 has a rectangular shape having long sides parallel to the second direction Y. In the example of FIG. 16, the pixel electrodes PE1, PE2, and PE3 have the same area. Note that the shape of the pixel electrodes PE1, PE2, and PE3 is not limited to that of the example shown in FIG. 16.

The display device DSP further comprises partitions P11, P12, P13, and P14 included in an optical control element OD. Each of the partitions P11, P12, P13, and P14 extend in the second direction Y in which the pixels PX1 and PX2 are arranged. The partitions P11 and P12 sandwich the pixel electrode PE1 of the pixel PX1 along the first direction X in plan view. The partitions P12 and P13 sandwich the pixel electrode PE2 of the pixel PX1 along the first direction X in plan view. The partitions P13 and P14 sandwich the pixel electrode PE3 of the pixel PX1 along the first direction X in plan view.

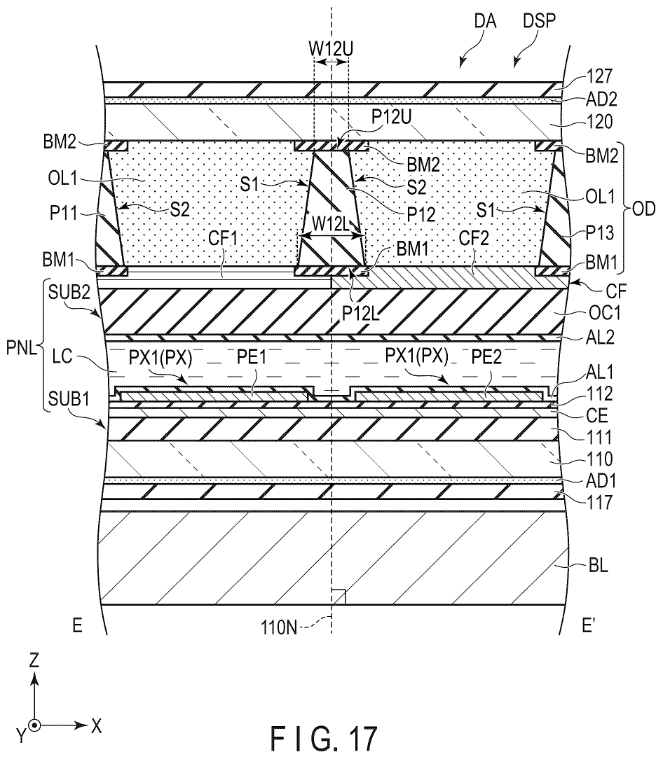

Similarly to the partitions P11, P12, and P13 of the first embodiment shown in FIG. 3, the partitions P11, P12, P13, and P14 overlap the pixel PX1 in the third direction Z but do not overlap the pixel PX2. FIG. 17 is a cross-sectional view showing the configuration example of the display device DSP along line E-E′ in FIG. 16. The display device DSP comprises the display panel PNL, an illumination device BL, and polarizers 117 and 127.

The first substrate SUB1 comprises a first transparent substrate 110, insulating layers 111 and 112, a common electrode CE, a plurality of pixel electrodes PE, and a first alignment film AL1. The first substrate SUB1 is provided above the illumination device BL. The insulating layer 111 is provided on the first transparent substrate 110. The common electrode CE is provided over a plurality of pixels PX on the insulating layer 111. The common electrode CE may be provided on the second substrate SUB2. The insulating layer 12 is provided on the common electrode CE. The pixel electrodes PE1 and PE2 are arranged for the respective pixels PX on the insulating film 12. In the illustrated example, the pixel electrodes PE1 and PE2 are provided between the first transparent substrate 110 and the liquid crystal layer LC. The first alignment film AL1 covers the pixel electrodes PEL and PE2 and the insulating layer 112. The scanning lines GL, the signal lines SL, and the switching elements SW shown in FIG. 15 are provided between the transparent substrate 110 and the common electrode CE.

The second substrate SUB2 comprises a second transparent substrate 120, the optical control element OD, a color filter layer CF, an overcoat layer OC1, and an alignment film AL2. The second transparent substrate 120 faces the first transparent substrate 110 in the third direction Z. The second substrate SUB2 is provided above the first substrate SUB1. The alignment film AL2 is provided below the transparent substrate 120.

The optical control element OD comprises the partitions P11, P12, P13, and P14, a transparent optical layer OL1, and a plurality of light-shielding layers BM1 and BM2. The optical control element OD is provided between the second transparent substrate 120 and the liquid crystal layer LC. In the illustrated example, the optical control element OD is provided below the second transparent substrate 120.

The bottom surface P12L of the partition P12 faces the liquid crystal layer LC in the third direction Z. The upper surface P12U of the partition P12 faces the second transparent substrate 120 in the third direction Z. Each of the side surfaces S1 and S2 of the partition P12 is inclined with respect to the normal 110N of the first transparent substrate 110 such that the width W12L of the bottom surface P12L is greater than the width W12U of the upper surface P12U (W12L>W12U). That is, the partition P12 has a tapered cross section in which the width along the first direction X decreases as the partition P12 extends from the liquid crystal layer LC. The optical layer OL1 overlaps the pixel electrodes PE1 and PE2 in the third direction Z.

The plurality of light-shielding layers BM2 (second light-shielding layers) are located between the second transparent substrate 120 and the respective partitions P11, P12, and P13. The plurality of light-shielding layers BM2 overlap the respective partitions P11, P12, and P13. The light-shielding layer BM2 overlapping the partition P12 covers the entire upper surface P12U. The light-shielding layers BM2 that overlap each of the partitions P11 and P13 have the same shape as the light-shielding layer BM2 that overlaps the partition P12.

The color filter layer CF is provided between the liquid crystal layer LC and the optical layer OL1. The color filter CF1, blue color filer, overlaps the pixel electrode PE1. The color filter CF2, green color filter, overlaps the pixel electrode PE2. Though not illustrated, the color filter layer CF comprises a red color filter overlapping the pixel electrode PE3. The color filter layer CF may be provided on the first substrate SUB1.

The light-shielding layer BM1 (the first light-shielding layer) is provided between color filter layer of colors different from each other. In the example of FIG. 17, the light-shielding layer BM1 is located between the color filter CF1 and the color filter CF2 and between the partitions P11, P12, and P13 and the color filter layer CF. The plurality of the light-shielding layers BM1 overlap the respective partitions P11, P12, and P13. The light-shielding layer BM1 overlapping the partition P12 covers the entire bottom surface P12L. The light-shielding layer BM1 overlapping each of the partitions P11 and P13 has the same shape as the light-shielding layer BM1 overlapping the partition P12.

The overcoat layer OC1 is provided between the color filter layer CF and the liquid crystal layer LC. The overcoat layer OC1 covers the color filter layer CF. The alignment film AL2 covers the overcoat layer OC1. The liquid crystal layer LC is provided between the first transparent substrate 110 and the second transparent substrate 120. In the illustrated example, the liquid crystal layer LC is provided between the alignment film AL1 and the alignment film AL2.

The polarizer 117 is bonded to the lower surface of the first transparent substrate 110 by an adhesive AD1. The polarizer 127 is bonded to the upper surface of the second transparent substrate 120 by an adhesive AD2. For example, the polarization axes of the polarizers 117 and 127 are orthogonal to each other in the X-Y plane.

The first transparent substrate 110 and the second transparent substrate 120 are insulating substrates such as glass substrates and plastic substrates. The insulating layer 111 includes an inorganic insulating layer and an organic insulating layer. The inorganic insulating layer 112 is an inorganic insulating layer. The pixel electrodes PE1 and PE2 and the common electrode CE are transparent electrodes. The overcoat layer OC1 is formed of a transparent resin material. The alignment films AL1 and AL2 are horizontal alignment films having an alignment restriction force substantially parallel to the X-Y plane. The configuration is not limited to this example.

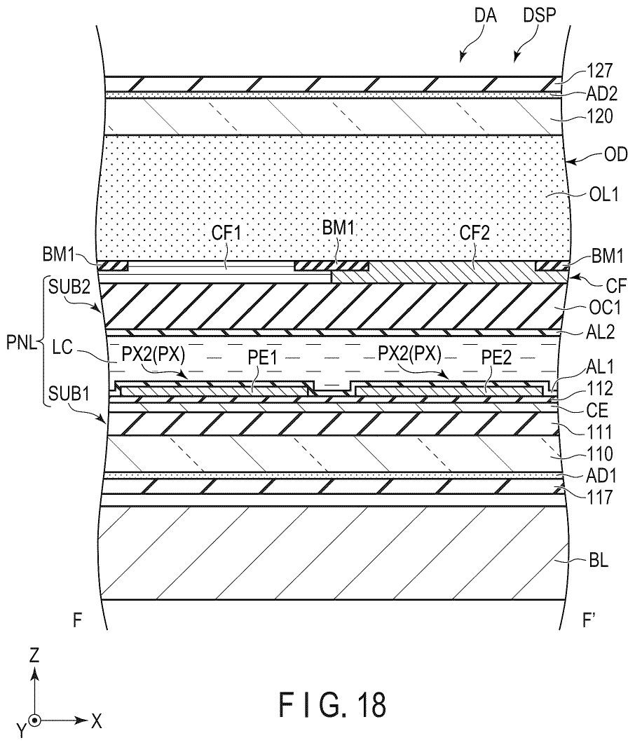

FIG. 18 is a cross-sectional view showing the configuration example of the display device DSP along line E-E′ in FIG. 16.

The optical layer OL1 overlaps the pixel electrodes PE1 and PE2 of the pixel PX2 in the third direction Z. In this manner, among the optical control elements OD, the optical layer OL1 overlaps the pixel PX2, but the partition does not overlap the pixel PX2.

The display device DSP of the second embodiment can exhibit the same effects as those exhibited by the display device DSP of the first embodiment.

In the above example, for example, each of the pixel electrodes PE1, PE2, and PE3 of the pixel PX1 corresponds to the first pixel electrode, each of the pixel electrodes PE1, PE2, and PE3 of the pixel PX2 corresponds to the second pixel electrode, and each of the partitions P11, P12, P13, and P14 corresponds to the first partition. When the pixel electrode PE1 of the pixel PX1 corresponds to the first pixel electrode, the partitions P11 and P12 correspond to a pair of the first partitions. When the pixel electrode PE2 of the pixel PX1 corresponds to the first pixel electrode, the partitions P12 and P13 correspond to a pair of the first partitions. When the pixel electrode PE3 of the pixel PX1 corresponds to the first pixel electrode, the partitions P13 and P14 correspond to a pair of the first partitions.

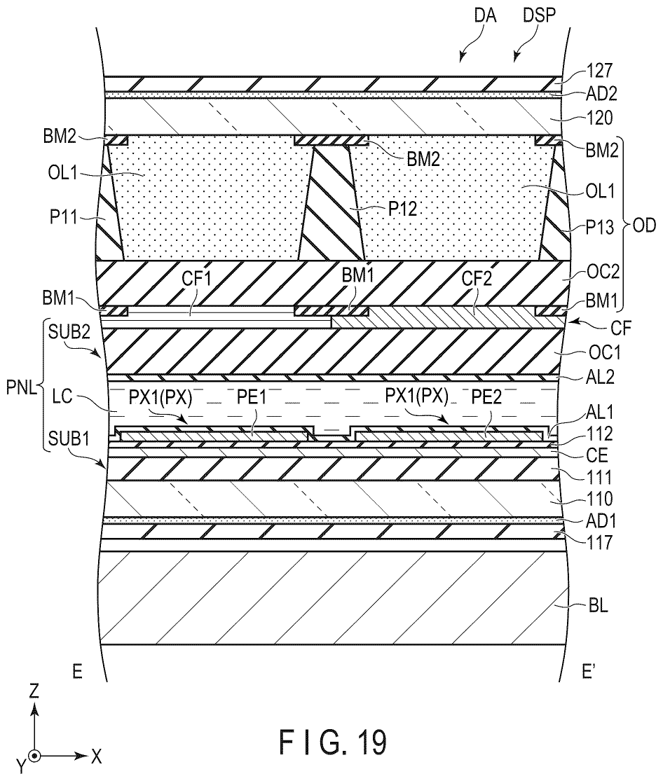

FIG. 19 is a cross-sectional view showing another configuration example of the display device DSP along line E-E′ in FIG. 16. The display device DSP shown in FIG. 19 is different from the display device DSP shown in FIG. 17 in the point that the optical control element OD comprises an overcoat layer OC2.

The optical control element OD further comprises the overcoat layer OC2. The overcoat layer OC2 covers the partitions P11, P12, and P13 and the overcoat layer OL1 and is provided between the overcoat layer OL1 and the color filter layer CF. The overcoat layer OC2 is formed of, for example, a transparent resin material such as acrylic resin.

The overcoat layer OC2 has the function of planarizing the irregularities formed by the partitions P11, P12, and P13 and the optical layer OL1 in the optical control element OD. The overcoat layer OC2 prevents the dye of the color filter layer CF from entering the optical layer OL1.

The display device DSP shown in FIG. 19 can exhibit the same effects as those achieved by the display device DSP shown in FIG. 17.

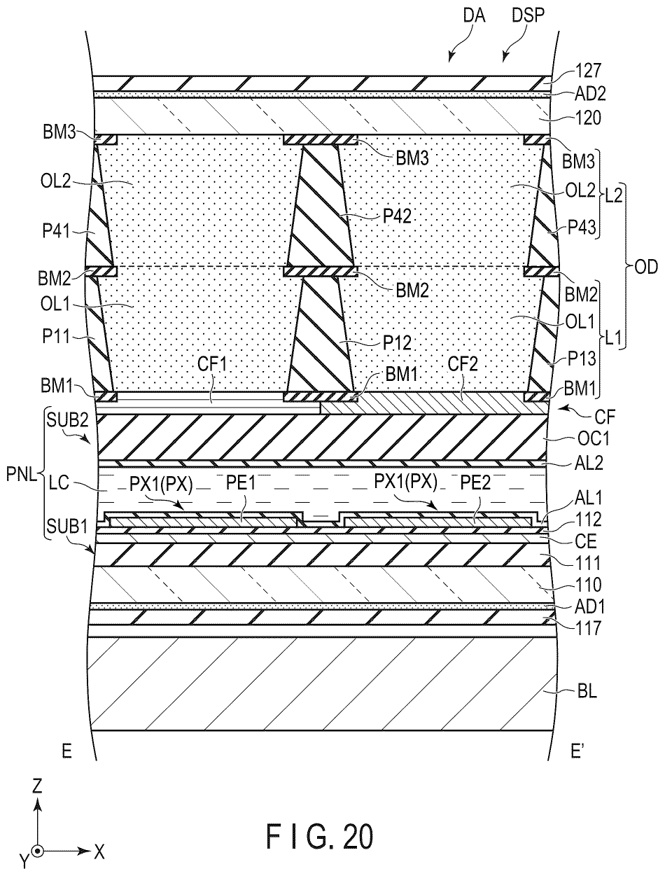

FIG. 20 is a cross-sectional view showing yet another configuration example of the display device DSP along line E-E′ in FIG. 16. The display device DSP shown in FIG. 20 is different from the display device DSP shown in FIG. 17 in the point that the optical control element OD is formed as a multilayer body.

The optical control element OD comprises a first layer L1 and a second layer L2. These first layer L1 and the second layer L2 have the configurations same as those of the first layer L1 and the second layer L2 of the first embodiment shown in FIG. 10.

The display device DSP shown in FIG. 20 can exhibit the same effects as those achieved by the display device DSP shown in FIG. 10.

All of the display devices that can be implemented by a person of ordinary skill in the art through arbitrary design changes to the display device described above as the embodiment of the present invention come within the scope of the present invention as long as they are in keeping with the spirit of the present invention.

Various types of the modified examples are easily conceivable within the category of the ideas of the present invention by a person of ordinary skill in the art and the modified examples are also considered to fall within the scope of the present invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device, comprising:
a substrate;
a first display element provided above the substrate;
a sealing layer covering the first display element; and
an optical control element overlapping the sealing layer, wherein
the optical control element includes:
a plurality of partitions including a pair of first partitions sandwiching the first display element in plan view; and
an optical layer located between the pair of the first partitions, in contact with a side surface of the first partition, and overlapping the first display element, and
a refractive index of each of the partitions is smaller than a refractive index of the optical layer.

2. The display device of claim 1, wherein
the first display element includes:
a lower electrode;
an organic layer including a light emitting layer overlapping the lower electrode; and
an upper electrode overlapping the organic layer, wherein
the display device further comprises a rib surrounding the lower electrode and the light emitting layer in plan view, and
the first partition overlaps the rib.

3. The display device of claim 1, wherein
each of the partitions has a tapered cross section whose width decreases as being farther from the sealing layer, and
the side surface is inclined with respect to a normal of the substrate.

4. The display device of claim 1, further comprising:
a polarizer bonded to the optical control element.

5. The display device of claim 1, further comprising:
a color filter overlapping the first display element.

6. The display device of claim 1, wherein
the refractive index of the optical layer and a refractive index of the sealing layer are equivalent to each other.

7. The display device of claim 1, wherein
each of the partitions includes a bottom surface facing the sealing layer, and
the optical control element further comprises a first light-shielding layer covering the bottom surface.

8. The display device of claim 1, wherein
the plurality of partitions further include a second partition located between the pair of the first partitions in plan view and overlapping the first display element.

9. The display device of claim 1, wherein
the plurality of partitions further include a pair of third partitions intersecting the pair of the first partitions in plan view and sandwiching the first display element.

10. The display device of claim 1, further comprising:
a second display element adjacent to the first display element, wherein
the plurality of partitions include no partitions sandwiching the second display element in plan view, and
the optical layer overlaps the second display element.

11. A display device, comprising:
a first transparent substrate;
a second transparent substrate facing the first transparent substrate;
a liquid crystal layer located between the first transparent substrate and the second transparent substrate;
a first pixel electrode provided between the first transparent substrate and the liquid crystal layer; and
an optical control element provided between the second transparent substrate and the liquid crystal layer, wherein
the optical control element includes:
a plurality of partitions including a pair of first partitions sandwiching the first pixel electrode in plan view; and
an optical layer located between the pair of the first partitions, in contact with a side surface of the first partition, and overlapping the first pixel electrode, and
a refractive index of each of the partitions is smaller than a refractive index of the optical layer.

12. The display device of claim 11, wherein
each of the partitions has a tapered cross section whose width decreases as being farther from the liquid crystal layer, and
the side surface is inclined with respect to a normal of the first transparent substrate.

13. The display device of claim 11, further comprising:
a color filter provided between the liquid crystal layer and the optical layer and overlapping the first pixel electrode.

14. The display device of claim 13, further comprising:
an overcoat layer covering the color filter and provided between the color filter layer and the liquid crystal layer.

15. The display device of claim 13, wherein
the optical control element further comprises an overcoat layer covering the plurality of partitions and the optical layer and located between the optical layer and the color filter.

16. The display device of claim 12, wherein
each of the partitions includes a bottom surface facing the liquid crystal layer, and
the optical control element further comprises a first light-shielding layer covering the bottom surface.

17. The display device of claim 11, further comprising:
a second pixel electrode adjacent to the first pixel electrode, wherein
the plurality of partitions include no partitions sandwiching the second pixel electrode in plan view, and
the optical layer overlaps the second pixel electrode.

18. The display device of claim 7, wherein
each of the partitions further includes an upper surface located on a side opposite to the bottom surface, and
the optical control element further comprises a second light-shielding layer covering the upper surface of the partition.

19. The display device of claim 1, wherein
a refractive index difference between the refractive index of the partition and the refractive index of the optical layer is 0.2 or more.

20. The display device of claim 1, wherein
the partition is a light absorbing body.
